(19) United States
(12) Patent Application Publication
(10) Pub. No.: US 2017/0009343 A1
(43) Pub. Date: Jan. 12, 2017

(54) ATOMIC LAYER DEPOSITION APPARATUS AND ATOMIC LAYER DEPOSITION SYSTEM

(71) Applicant: VNI SOLUTION CO., LTD, Daejeon (KR)

(72) Inventor: Saeng Hyun CHO, Suwon-si (KR)

(73) Assignee: VNI SOLUTION CO.,LTD, Daejeon (KR)

(21) Appl. No.: 15/121,228

(22) PCT Filed: Feb. 27, 2015
(86) PCT No.: PCT/KR2015/001959

§ 371 Date: Aug. 24, 2016

(30) Foreign Application Priority Data
Feb. 27, 2014 (KR) 10-2014-0023002
Oct. 10, 2014 (KR) 10-2014-0136990
Oct. 18, 2014 (KR) 10-2014-0141252

(51) Int. Cl. C23C 16/455; C23C 16/04; C23C 16/44; C23C 16/458; H01L 51/56; H01L 51/52

(52) U.S. Cl. CPC C23C 16/45544; H01L 51/56; H01L 51/5253; C23C 16/4412; C23C 16/458; C23C 16/042

(57) ABSTRACT

An atomic layer deposition apparatus and an atomic layer deposition system, capable of reducing space for installing the apparatus and significantly improving production speed by forming a thin film on a surface of each of a plurality of rectangular substrates by rotating the substrates with respect to a gas spray portion, with the substrates being supported by one substrate support portion. The atomic layer deposition apparatus includes: a vacuum chamber; a gas supply portion, which is provided above or below the vacuum chamber, and which supplies gas so that a thin film is deposited on a surface of each of substrates; and a substrate support portion, which is provided in the vacuum chamber so as to horizontally rotate about the gas supply portion, and which supports the two or more rectangular substrates arranged in the circumferential direction with respect to the center of rotation of the substrate support portion.

### CROSS-REFERENCE TO RELATED APPLICATIONS

This U.S. non-provisional patent application claims priority under 35 U.S.C. §119 of Korean Patent Application Nos. 10-2014-0023002, filed on Feb. 27, 2014, 10-2014-0136990, filed on Oct. 10, 2014, and 10-2014-0141252, filed on Oct. 18, 2014, the entire contents of which are hereby incorporated by reference.

### TECHNICAL FIELD

The present invention disclosed herein relates to an atomic layer deposition apparatus and an atomic layer deposition system.

### BACKGROUND ART

An organic electroluminescent display device is a self-light emitting type display electrically exciting a fluorescent organic compound to emit light. The organic electroluminescent display device is being spotlighted as a next generation display because it can be driven at a low voltage and easily manufacture in slim, and have a wide viewing angle and a quick response speed.

However, a light emitting layer of an organic electroluminescent device can be damaged when exposed to moisture and oxygen. Accordingly, an encapsulation means is provided on a substrate on which the organic electroluminescent device is provided to prevent the organic electroluminescent device from being damaged by the moisture and the oxygen. The encapsulation means may include an encapsulation substrate and an encapsulation thin film. In recent years, the encapsulation thin film is generally used for the encapsulation means according to miniaturization and slimness of the display.

The above-described encapsulation thin film is formed in such a manner that at least four inorganic films and organic films are alternately laminated and has a thickness of about 0.5 μm to about 10 μm. For example, the encapsulation thin film may be formed by alternately laminating a first organic film, a first inorganic film, a second organic film, and a second inorganic film.

As the encapsulation thin film formed by the inorganic film and the organic film is applied to the organic electroluminescent display device, the organic electroluminescent display device may have a slim thickness.

For example, the slim type encapsulation thin film formed in the organic electroluminescent display device may be made of Al₂O₃ and AlON.

The slim type encapsulation thin film formed in the organic electroluminescent display device may be formed through various processes and, especially, formed by an atomic layer deposition process of forming the thin film by sequentially spraying source gas such as TMA and reaction gas such as O₂, NH₃, and NO₂ while the substrate is linearly moved in a vacuum chamber.

However, as the conventional atomic layer deposition apparatus, which forms the thin film on a surface of the substrate by spraying the source gas and the reaction gas while the substrate is linearly moved, requires the linear movement of the substrate, a linear movement space of the substrate is additionally required to increase a size of the vacuum chamber, thereby increasing an installation space of the apparatus and manufacturing costs of the apparatus.

In addition, since the thin film is formed while linearly moved when the thin film is formed on the surface of the substrate, the processing time increases and resultantly the productivity of the substrate is lowered.

### DISCLOSURE OF THE INVENTION

### Technical Problem

The objective of the present invention is to provide an atomic layer deposition apparatus and an atomic layer deposition system, which are capable of reducing a space for installing the apparatus and significantly improving a production speed by forming a thin film on a surface of each of a plurality of rectangular substrates by rotating the substrates with respect to a gas injection unit in a state in which the plurality of rectangular substrates are supported by one substrate support unit.

### Technical Solution

In accordance with an embodiment of the present invention, an atomic layer deposition apparatus includes: a vacuum chamber; a gas injection unit installed above or below the vacuum chamber to supply a gas so that a thin film is deposited on a surface of a substrate; a substrate support unit installed in the vacuum chamber to relatively and horizontally rotate with respect to the gas injection unit and supporting two or more rectangular substrates arranged in a circumferential direction with respect to a center of rotation thereof, wherein the gas injection unit includes at least one source gas injection unit arranged in a rotational direction of the substrate to spray source gas and at least one reaction gas injection unit for spraying reaction gas that is in a plasma state, an exhaust unit for absorbing and exhausting the gas is installed on at least one area between the spray units, a mask having at least one opening defined in a surface, which faces the gas injection unit, is closely attached to the substrate supported by the substrate support unit, and the atomic layer deposition apparatus further includes at least one alignment unit for aligning relative positions of the substrate and the mask.

The alignment unit may be installed corresponding to the number of the substrates supported by the substrate support unit.

The alignment unit for aligning the mask M with the substrate S before performing the thin film deposition process on the surface of the substrate S, the alignment unit may include: a first alignment unit 100 for sequentially and firstly aligning the substrate S with the mask M by first relative displacement between the substrate S and the mask M; and a second alignment unit 200 for sequentially and secondarily aligning the substrate S with the mask M by second relative displacement between the substrate S and the mask M after the first alignment by the first alignment unit 100, and a displacement scale of the second relative displacement is less than that of the first relative displacement.

The first alignment unit 100 and the second alignment unit 200 may be coupled to a mask support unit 310 for supporting the mask M and move the mask support unit 310, thereby performing the first relative displacement and the second relative displacement of the mask M supported by the mask support unit 310 with respect to the substrate S.

The first alignment unit 100 and the second alignment unit 200 may be coupled to a substrate support unit 320 for supporting the substrate S and move the substrate support unit 320, thereby performing the first relative displacement and the second relative displacement of the substrate S supported by the substrate support unit 320 with respect to the mask M.

The second alignment unit 200 may be coupled to a mask support unit 310 for supporting the mask M and move the mask support unit 310, thereby performing the second relative displacement of the mask M supported by the mask support unit 310 with respect to the substrate S, and the first alignment unit 100 may be coupled to a substrate support unit 320 for supporting the substrate S and move the substrate support unit 320, thereby performing the first relative displacement of the substrate S supported by the substrate support unit 320 with respect to the mask M.

The first alignment unit 100 may be coupled to a mask support unit 310 for supporting the mask M and move the mask support unit 310, thereby performing the first relative displacement of the mask M supported by the mask support unit 310 with respect to the substrate S, and the second alignment unit 200 may be coupled to a substrate support unit 320 for supporting the substrate S and move the substrate support unit 320, thereby performing the second relative displacement of the substrate S supported by the substrate support unit 320 with respect to the mask M.

In accordance with another embodiment of the present invention, an atomic layer deposition system includes: at least one transfer apparatus in which a transfer robot is installed; and a plurality of atomic layer deposition apparatuses of any one of claims 1 to 7, the plurality of atomic layer deposition apparatuses being coupled to the transfer apparatus to receive a substrate by the transfer robot.

### Advantageous Effects

According to the present invention, the atomic layer deposition apparatus and the atomic layer deposition system may reduce the installation space for the apparatus and significantly improve the production speed by forming the thin film on the surface of the substrate by the relative rotation with respect to the gas injection unit in the state in which the plurality of substrates are supported by one substrate support unit in one vacuum chamber.

Especially, the conventional atomic layer deposition apparatus, which deposits the thin film by using the linear movement of the substrate when the atomic layer deposition process is performed, performs the substrate processing for one substrate at a time and secure the space for linear movement of the substrate. However, the atomic layer deposition apparatus and the atomic layer deposition system according to the present invention may process two or more substrates in one vacuum chamber to maximize the space efficiency of the apparatus.

Also, the conventional atomic layer deposition apparatus, which deposits the thin film by using the linear movement of the substrate when the atomic layer deposition process is performed, has a limitation in reducing the distance between the source gas injection unit and the reaction gas injection unit due to particle generated by reaction between the source gas and the reaction gas. However, the atomic layer deposition apparatus and the atomic layer deposition system according to the present invention may relatively and freely reduce the distance between source gas injection unit and the reaction gas injection unit because the thin film deposition process is performed by rotation.

According to another aspect of the present invention, the substrate and the mask may be quickly and precisely aligned by performing the second relative displacement between the substrate S and the mask M with the relatively small displacement scale after finishing the first relative displacement between the substrate S and the mask M with the relatively large displacement scale.

According to another aspect of the present invention, when the closely attaching process and the alignment process are performed at the same time, the alignment method according to the present invention may minimize the time for performing process in comparison with that of the related art that performs the alignment process in the state in which the distance between the substrate S and the mask M is fixed.

According to another aspect of the present invention, as the alignment between the substrate S and the mask M is performed in the state in which the substrate S and the mask M are closely attached to each other according to the measurement result, the alignment method according to the present invention may further quickly and exactly perform the alignment process when the alignment process of the substrate S and the mask M is performed.

### BRIEF DESCRIPTION OF THE DRAWINGS

FIG. 1 is a plan view illustrating an atomic layer deposition system according to a first embodiment of the present invention,

FIG. 2 is a plan view illustrating embodiments in which atomic layer deposition apparatuses of the atomic layer deposition system in FIG. 1 are arranged in which two substrates are deposited,

FIG. 3 is a plan view illustrating embodiments in which atomic layer deposition apparatuses of the atomic layer deposition system in FIG. 1 are arranged in which three substrates are deposited,

FIG. 4 is a plan view illustrating embodiments in which atomic layer deposition apparatuses of the atomic layer deposition system in FIG. 1 are arranged in which four substrates are deposited,

FIG. 5 is a longitudinal cross-sectional view of FIG. 4,

FIG. 6 is a plan view illustrating a first embodiment of a gas injection unit of the atomic layer deposition apparatus of the atomic layer deposition system in FIG. 1,

FIGS. 7A and 7B are plan views illustrating different embodiments of the gas injection unit of the atomic layer deposition apparatus of the atomic layer deposition system in FIG. 1,

FIG. 8 is plan view illustrating a different embodiment of the gas injection unit of the atomic layer deposition apparatus of the atomic layer deposition system in FIG. 1,

FIGS. 9A to 9C are partial cross-sectional views respectively illustrating constitutional examples of the gas injection units in FIGS. 6 to 8,

FIG. 10 is a plan view of an atomic layer deposition system according to a second embodiment of the present invention,

FIG. 11 is a plan view of an atomic layer deposition system according to a third embodiment of the present invention,

FIG. 12 is a partial plan view illustrating an alignment process of a substrate and a mask in FIG. 6,

FIG. 13 is a plan view illustrating a first embodiment of an alignment unit of the atomic layer deposition apparatus in FIG. 1,

FIG. 14 is a partial plan view illustrating a first alignment unit of FIG. 13,

FIG. 15 is a partial side view illustrating a second alignment unit of FIG. 13,

FIG. 16 is a plan view illustrating a second embodiment of the alignment unit of the atomic layer deposition apparatus in FIG. 1,

FIG. 17 is a plan view illustrating a third embodiment of the alignment unit of the atomic layer deposition apparatus in FIG. 1,

FIG. 18 is a plan view illustrating a fourth embodiment of the alignment unit of the atomic layer deposition apparatus in FIG. 1,

FIG. 19 is a partial cross-sectional view illustrating the substrate and the mask for performing the alignment by the alignment units in FIGS. 13 to 18,

FIG. 20 is a partial plan view illustrating an alignment error between the substrate and the mask, and

FIG. 21 is a cross-sectional view illustrating an embodiment of a distance detection unit for detecting a distance between the substrate S and the mask M.

### MODE FOR CARRYING OUT THE INVENTION

Hereinafter, embodiments of the present invention will be described with reference to the accompanying drawings.

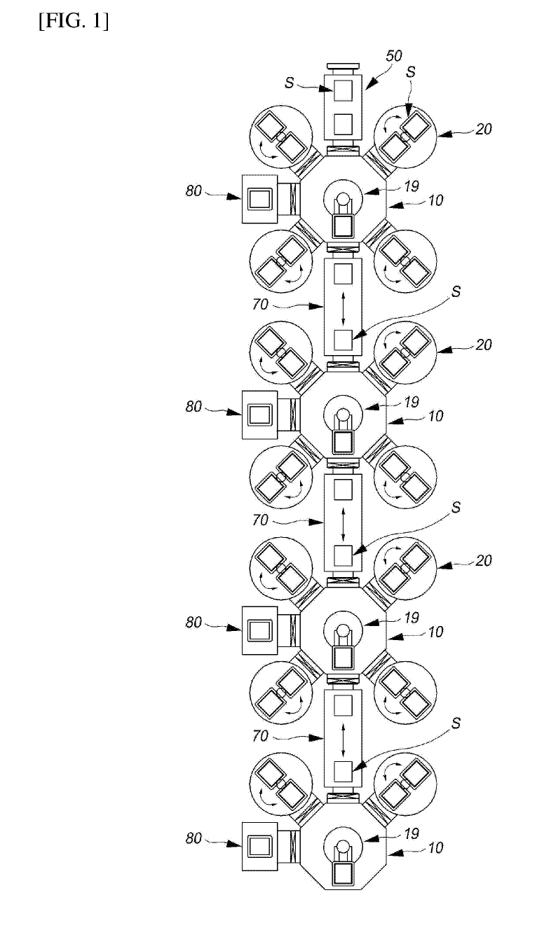

As shown in FIG. 1, an atomic layer deposition system according to a first embodiment of the present invention may include at least one transfer apparatus 10 in which a transfer robot 19 is installed and a plurality of atomic layer deposition apparatuses each of which is coupled to the transfer apparatus 10 to receive a substrate S by the transfer robot 19.

The transfer apparatus 10 transfers the substrate S to each of the atomic layer deposition apparatuses 20. The transfer apparatus 10 may be variously provided.

The transfer apparatus 10 according to an embodiment may include a transfer chamber to which the atomic layer deposition apparatuses 20 are coupled and the transfer robot 19 installed in the transfer chamber to transfer the substrate S.

The transfer chamber provides a space for installing the transfer robot 19 and a sealed space capable of maintaining a vacuum pressure that is almost the same as that of the atomic layer deposition apparatus 20. The transfer chamber may be variously provided.

In addition to the atomic layer deposition apparatus 20, the transfer chamber may be coupled to a load-lock device 50 through which the substrate S is introduced from the outside, an unload-lock device (not shown) through which the substrate S is discharged to the outside, a buffer device 70 for temporarily storing the substrate S, and a mask storing device 80 for temporarily storing the mask.

The above-described load-lock device 50 and the unload-lock device may be separately provided or integrated in one as shown in FIG. 1 depending on a transfer type of the substrate S.

Also, the buffer device 70 may be positioned at various positions in consideration of transfer efficiency of the substrate S, and connect the transfer apparatuses 10 to transfer the substrate S and temporarily store the substrate S at the same time when the plurality of transfer apparatuses 10 are installed as shown in the drawings.

Meanwhile, the atomic layer deposition system according to the present invention may be variously provided depending on the transfer apparatus 10 and the devices coupled thereto as shown in FIGS. 1, 10, and 11.

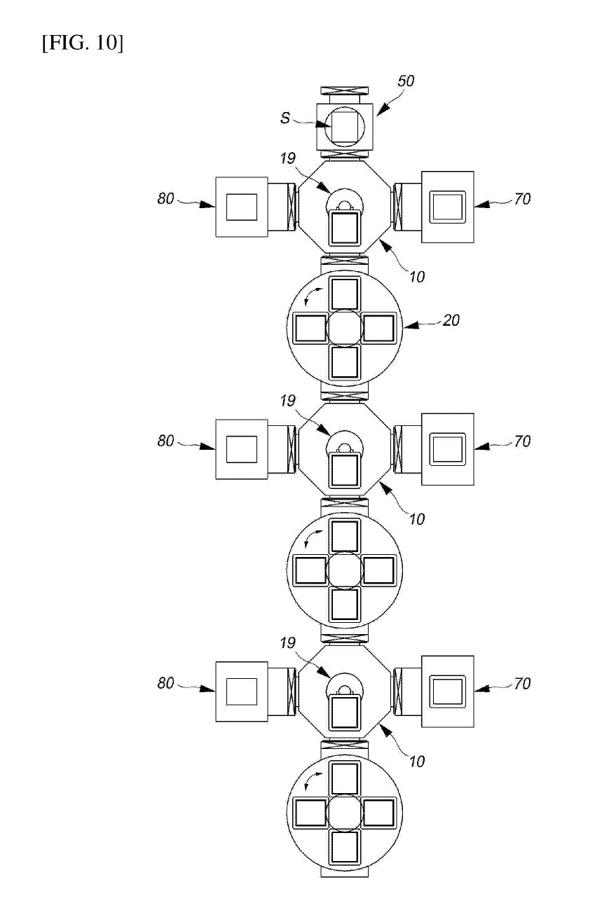

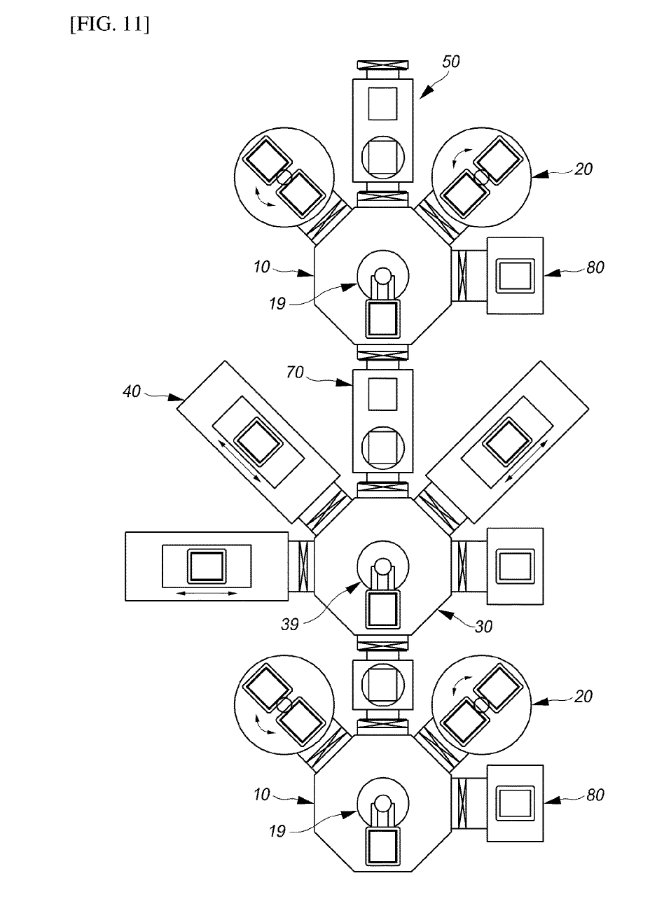

As shown in FIG. 10, an atomic layer deposition system according to a second embodiment of the present invention may include a plurality of transfer apparatuses 10 in which the transfer robots 19 are respectively installed and which are arranged in a line and a plurality of atomic layer deposition apparatuses 20 respectively arranged between the plurality of transfer apparatuses 10 to receive the substrate S by the transfer robot 19.

The atomic layer deposition system according to the second embodiment of the present invention is the same as or similar to the first embodiment except that the transfer apparatus 10 and the atomic layer deposition apparatus 20 are sequentially, i.e., inline, installed. Detailed description for this will be omitted.

In the atomic layer deposition system according to the second embodiment, the atomic layer deposition apparatus 20 may perform two or more thin film deposition processes at a time to have a small installation space and quickly perform a process in comparison with the related art.

Especially, the atomic layer deposition apparatus 20 of the atomic layer deposition system according to the second embodiment may be optimized in sequentially forming an organic film, an inorganic film, and a monomer for an encapsulation process on the substrate through a series of processes in manufacturing an organic electroluminescent display device.

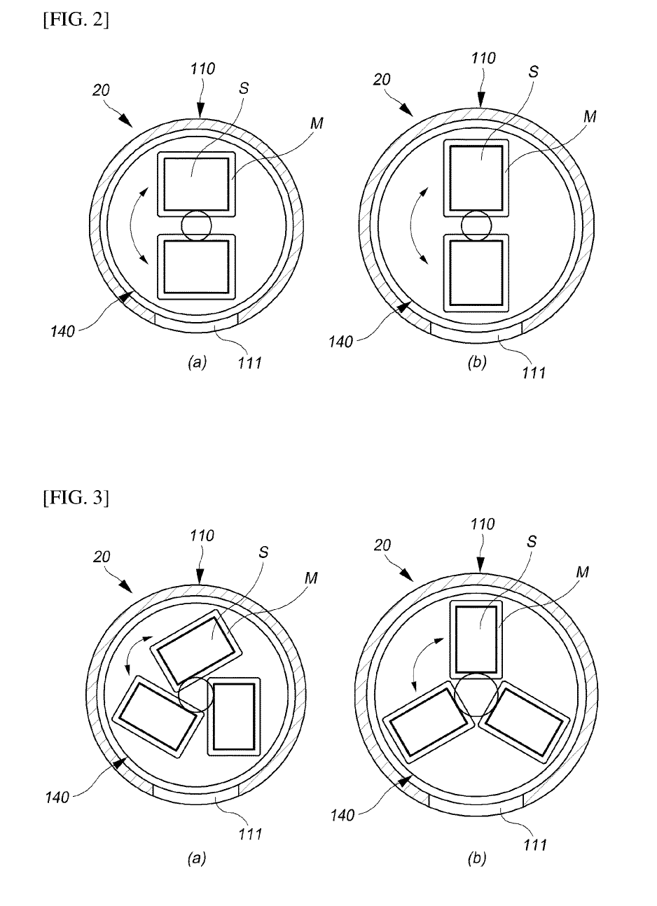

Also, as shown in FIG. 2, in the atomic layer deposition system according to the second embodiment, when two substrates S are disposed in the atomic layer deposition apparatus 20 to perform a process, the transfer apparatuses 10 are disposed opposite to each other to simultaneously perform substrate exchange, thereby increasing a total processing speed.

An atomic layer deposition system according to a third embodiment of the present invention is an example in which the atomic layer deposition apparatus 20 according to the present invention, which will be described later, and a linear movement atomic layer deposition apparatus 40 performing a substrate processing while linearly moving the substrate S are combined.

In detail, as shown in FIG. 11, in the atomic layer deposition system according to the third embodiment of the present invention, the linear movement atomic layer deposition apparatus 40 for linearly moving the substrate S and performing the substrate processing may be additionally coupled to the transfer apparatus 10 of the atomic layer deposition system according to the first embodiment, or the transfer chamber 30 to which only at least one linear movement atomic layer deposition apparatus 40 for linearly moving the substrate S and performing the substrate processing is coupled may be further provided.

As described above, when the atomic layer deposition apparatus 20 that will be described later and the linear movement atomic layer deposition apparatus 40 are combined, the processes may be selectively performed depending on the process and thin film characteristics to reduce an installation space and perform various kinds of processes.

Hereinafter, the atomic layer deposition apparatus according to the present invention will be described.

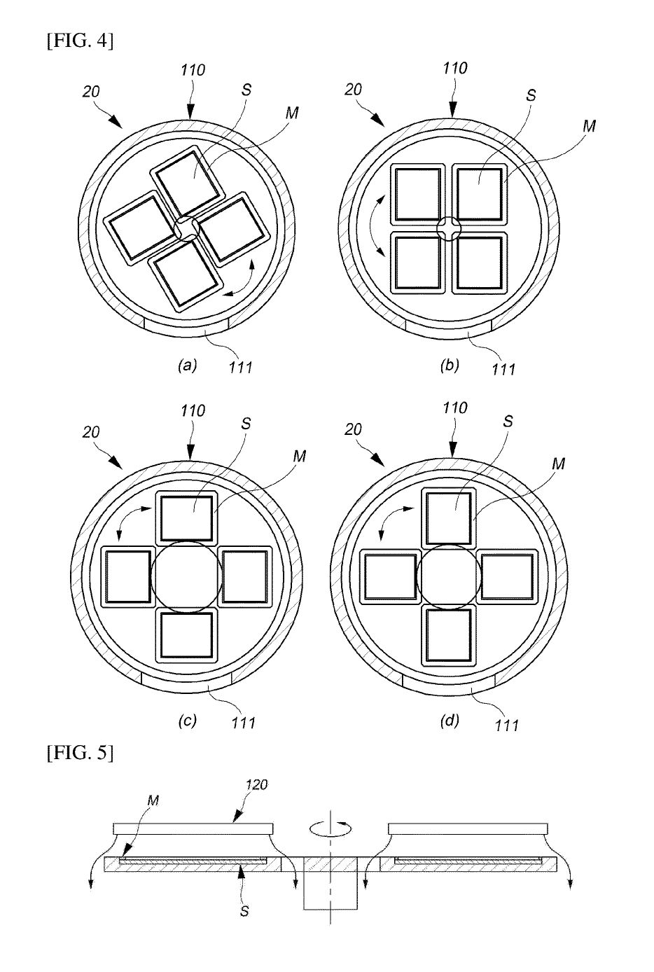

As shown in FIGS. 1 to 8, the atomic layer deposition apparatus 20 according to an embodiment of the present invention includes a vacuum chamber 110, a gas injection unit 120 installed above or below the vacuum chamber 110 to supply a gas so that a thin film is deposited on a surface of the substrate, and a substrate support unit 140 installed in the vacuum chamber to relatively and horizontally rotate with respect to the gas injection unit 120 and supporting two or more rectangular substrates S arranged in a circumferential direction with respect to a center of rotation thereof.

The gist of the present invention is that the thin film deposition process is performed in the vacuum chamber 110 by relatively rotating two or more rectangular substrates S, i.e., a plurality of rectangular substrates S with respect to the gas injection unit 120.

Especially, the substrate S that is an object to be processed by the atomic layer deposition apparatus according to the present invention may include any rectangular shaped substrate for which an apparatus for performing a process for a conventional circular wafer may not be used, e.g., a substrate for organic electroluminescent display device or a LCD panel substrate.

Also, one side of the rectangular substrate S desirably has a length of about 300 mm to 2,000 mm. This is because when the length of one side is less than about 300 mm, the footprint and the production speed insignificantly increase, and when greater than about 2,000 mm, the apparatus is difficult to be manufactured.

Here, two or more rectangular substrates may be variously arranged on the substrate support unit 140. This will be described later together with the substrate support unit 140.

The vacuum chamber 110 provides a processing environment for performing the thin film deposition process. The vacuum chamber 110 may be variously provided.

The vacuum chamber 110 may include a container having a predetermined inner space and a gate 111 through which the substrate S passes.

Also, the container may include an exhaust means for maintaining a predetermined pressure for the inner space.

The gas injection unit 120 installed above or below the vacuum chamber 110 to supply a gas so that a thin film is deposited on the surface of the substrate S. The gas injection unit 120 may be variously provided depending on a kind of the thin film deposition process.

When the thin film deposition process uses the atomic layer deposition process, as shown in FIG. 5, the gas injection unit 120 may include source gas injection unit, reaction gas injection unit, or the like and be provided in one or more to be installed above or below the substrate support unit 140.

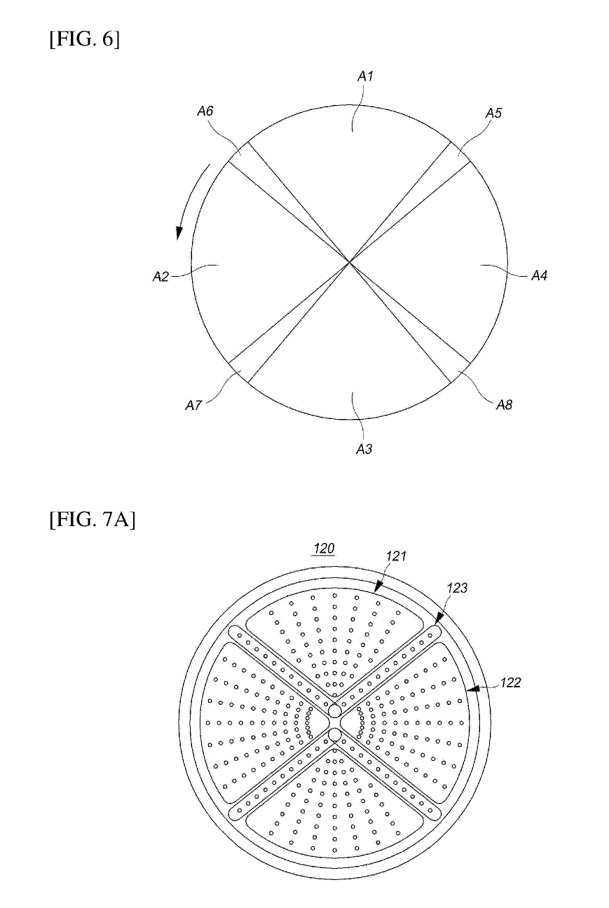

As shown in FIGS. 6 to 9C, the gas injection unit 120 according to an embodiment may include at least one source gas injection unit 121 arranged in a rotational direction of the substrate S to spray source gas and at least one reaction gas injection unit 122 for spraying reaction gas in a plasma state.

The source gas injection unit 121 may spray the source gas such as TMA, and the reaction gas injection unit 122 may spray the reaction gas such as O₂, NH₃, and NO₂. Here, properties of the source gas and the reaction gas are determined depending on the thin film to be formed on the substrate S.

The thin film made of Al₂O₃, AlON, or the like may be formed on the substrate S by the above-described source gas injection unit 121 and reaction gas injection unit 122.

Meanwhile, the reaction gas is necessarily converted into the plasma state when sprayed to the substrate S. Accordingly, the reaction gas injection unit 122 may convert the reaction gas into the plasma state by installing an electrode in a tube through which the reaction gas flows, i.e., a gas supply tube or by using RPG. The reaction gas injection unit 122 may be variously provided.

For example, the reaction gas injection unit 122 includes a flow path 131 in various types to spray the reaction gas supplied from reaction gas supply apparatus (not shown) for supplying the reaction gas to the substrate S.

Also, in the reaction gas injection unit 122, an induced electric field forming unit 130 forming the plasma by induced electric field is provided in the flow path 131 through which the reaction gas flows.

The induced electric field forming unit 130 for making the reaction gas in the plasma state by the induced electric field may include a dielectric 132 made of ceramic or quartz and at least one electrode 134 installed at an opposite side of the flow path 131 with respect to the dielectric 132 and to which RF power or AC power is applied.

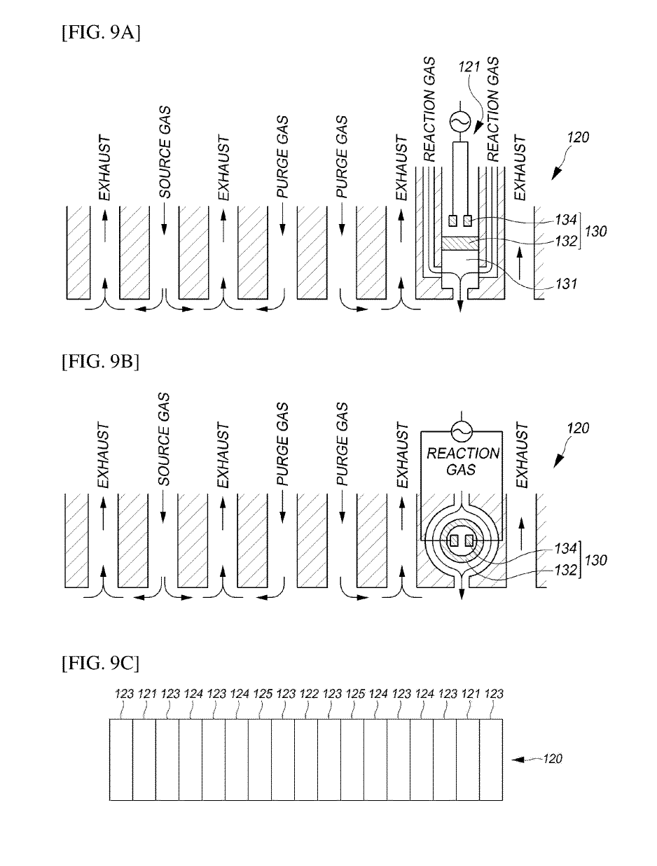

The dielectric 132 for forming the induced electric field by the electrode 134 may be installed on any position as long as the reaction gas in the flow path 131 is convertible into the plasma state by the induced electric field and constitute a portion of the flow path 131 as shown in FIGS. 9A and 9B.

As the electrode 134 has one end to which RF power or AC power is applied and the other end is grounded, the electrode 134 converts the reaction gas into the plasma state by the induced electric field through a medium of the dielectric 132.

The electrode 132 may have various shapes such as a circular rod and a plate and be provided in pair. Especially, the electrode 134 may be installed outside the vacuum chamber 110.

Meanwhile, the induced electric field forming unit 130 converts the reaction gas into the plasma state through an ICP method. The induced electric field forming unit 130 may be variously provided.

For example, as shown in FIG. 9B, the dielectric 22 may be constituted by a hollow tube arranged in a width direction of the substrate S.

Also, the electrode 134 may be installed in the tube of the dielectric 132 constituted by the hollow tube.

As described above, as the induced electric field formation unit 130 is provided in the flow path 131 through which the reaction gas flows, the reaction gas is easily converted into the plasma state, and an entire structure and assembly of the gas injection unit 120 is simplified.

Meanwhile, as shown in FIGS. 6 to 9C, the gas injection unit 120 may further include a purge gas injection unit 124 for spraying inert gas such as argon (Ar) to remove gases and particles remained on the substrate S in addition to the source gas injection unit 121 and the reaction gas injection unit 122.

The purge gas injection unit 124 sprays inert gas such as argon (Ar) to remove gases and particles remained on the substrate S in addition to the source gas injection unit 121 and the reaction gas injection unit 122. The number and the position of the purge gas injection unit 124 are determined in consideration of removal of the gases and particles.

Also, an exhaust unit 123 for absorbing and exhausting a gas may be installed on at least one area between the injection units 121 and 122 of the gas spray unit 120

The exhaust unit 123 for absorbing and exhausting the gas may be used to restrain particles generated from reaction between the reaction gas and the absorption gas by absorbing the source gas sprayed from the source gas injection unit 121 before the substrate S is transferred to an area to which the reaction gas is sprayed.

The installation position and the umber of the exhaust unit 123 are determined in consideration of mutual area separation between the reaction gas and the absorption gas or efficient exhaust of the gas.

Meanwhile, while the source gas and the spray gas respectively sprayed from the source gas injection unit 121 and the reaction gas injection unit 122 is sprayed onto the substrate, the source gas and the reaction gas are reacted to generate the particles above the substrate and resultantly form a porous thin film on the substrate.

Thus, the gas injection unit 120 may include the source gas injection unit 121, the reaction gas injection unit 122, the exhaust unit 123, and the purge gas injection unit 124 as shown in FIG. 9C.

That is, in the gas injection unit 120, the source gas injection unit 121 and the reaction gas injection unit 122 for spraying the reaction gas in the plasma state are sequentially and alternately installed in the relative movement direction with respect to the substrate, and a plasma absorption gas injection unit 125 for spraying plasma absorption gas reacting with negative ions of the reaction gas in the plasma state may be installed at the forward side and rear side of the reaction gas injection unit 122 in the a relative movement direction with respect to the substrate S.

Here, the plasma absorption gas injection unit 125 is installed at the forward side and the rear side of the reaction gas injection unit 122 and sprays the plasma absorption gas so that the plasma absorption gas reacts with the negative ions of the reaction gas in the plasma state to absorb the plasma.

For example, when the source gas is TMA and the reaction gas is one of O₂, NH₃ and N₂O, one of O₂ radical, NH₃ radical, N₂O radical, and H radical may be used as the absorption gas to absorb the negative ions (O⁻, NO₃⁻, NH₂⁻) of the reaction gas in the plasma state.

Meanwhile, the source gas injection unit 121, the reaction gas injection unit 122, and the exhaust unit 123, which constitute the gas injection unit 120, may have various shapes such as a line shape or a fan shape arranged in a radius direction from a center of rotation of the substrate support unit 140.

In detail, the source gas injection unit 121, the reaction gas injection unit 122, and the exhaust unit 123 may have various structures including a tube structure having a plurality of through-holes to spray or absorb a gas and a plate structure having a plurality of through-holes formed in a surface, which faces the substrate S, thereof.

Also, the source gas injection unit 121 and the reaction gas injection unit 122 may be variously installed in the above-described gas injection unit 120 depending on the gas spray method.

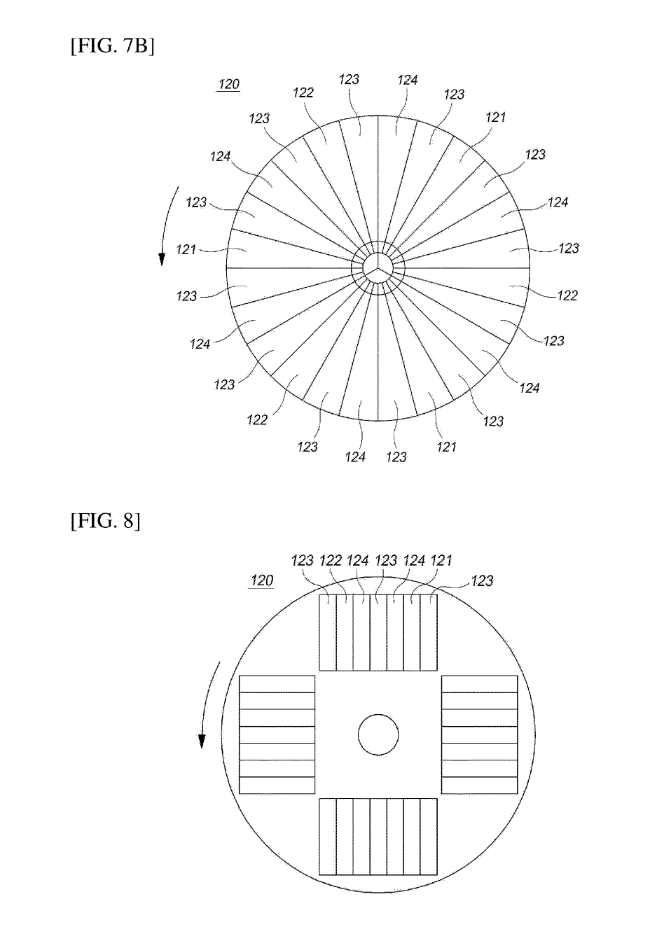

As shown in FIGS. 6 and 7A, as embodiments of the gas injection unit 120, a plurality of injection areas A1 to A8 divided in the rotational direction of the substrate support unit 140 may be arranged, and one of the source gas injection unit 121, the reaction gas injection unit 122, and the exhaust unit 123 that will be described later may be installed on each of the injection areas A1 to A8.

As shown in FIG. 7B, as another embodiment of the gas injection unit 120, a plurality of injection areas A1 to A8 divided in the rotational direction of the substrate support unit 140 may be arranged, and all of the source gas injection unit 121, the reaction gas injection unit 122, and the exhaust unit 123 that will be described later may be installed on each of the injection areas A1 to A8.

Here, the source gas injection unit 121 and the reaction gas injection unit 122 spray the source gas or the reaction gas with time difference to perform the atomic layer deposition process.

Here, the source gas and the reaction gas may be sprayed at the same time, and the source gas injection unit 121 and the reaction gas injection unit 122 may desirably have different positions, respectively.

As shown in FIG. 8, as another embodiment of the gas injection unit 120, a plurality of injection areas A1, A2, A3, and A4 each of which has a rectangular shape of which one side is perpendicular to a radius direction from a rotation center of the substrate support unit 140 may be arranged, and the source gas injection unit 121, the reaction gas injection unit 122, and the exhaust unit 123 may be arranged to be parallel to each other on each of the injection areas A1, A2, A3, and A4

The substrate support unit 140 is installed in the vacuum chamber 110 to relatively and horizontally rotate with respect to the gas injection unit 120 and supports two or more rectangular substrates S in the circumferential direction from the center of rotation thereof.

Here, as shown in FIGS. 2 to 4, the number of the substrate S arranged on the substrate support unit 140 may be determined in consideration of a process combination, a process speed, and a footprint, e.g., two, three, or four.

Here, when the substrate exchange with the transfer apparatus 10, the footprint, and the size of the apparatus are considered, it is desirable that two substrates S are arranged on the substrate support unit 140.

In detail, when two substrates S are arranged on the substrate support unit 140, the substrate exchange with the transfer apparatus 10 or the buffer device 70 are simultaneously performed at positions opposite to each other at the atomic layer deposition apparatus 20 to decrease the total process time.

Also, the substrate S may be variously arranged on the substrate support unit 140. For example, one side of the substrate S is perpendicular to or inclined to a rotational radius direction of the substrate support unit 140.

Especially, when one side of the rectangular substrate S is inclined, the size of the apparatus may be reduced in comparison with that of the apparatus when perpendicular.

The substrate support unit 140 according to an embodiment may rotate simultaneously with the gas injection unit 120 while relatively and horizontally rotating with respect to the gas injection unit 120, or while one of the gas injection unit 120 and the substrate support unit 140 is fixed, the other may rotate.

As shown in FIGS. 1 to 5b, the substrate support unit 140 according to an embodiment may include: a rotation support unit 141 installed in the vacuum chamber 110 to relatively and horizontally rotate with respect to the gas injection unit 120 and supporting two or more rectangular substrates S; and a rotation driving unit 142 for horizontally rotating the rotation support unit 141.

The rotation support unit 141 is installed in the vacuum chamber 110 to relatively and horizontally rotate with respect to the gas injection unit 120 and supporting two or more rectangular substrates S. The rotation support unit 141 may be variously provided.

The rotation support unit 141 according to an embodiment may include a support plate having a circular or polygonal shape. A support surface 143 supporting the substrate S may be recessed in the support plate to correspond to each of two or more rectangular substrates S.

Here, a top surface of the substrate S seated on the support surface 143 is desirably the same in height as a top surface of the support plate.

Also, the mask M having at least one opening may be closely attached to the support surface 143. Here, a top surface of the mask M covering the substrate S is desirably the same in height as the top surface of the support plate.

Meanwhile, at least one exhaust holes 144 are desirably formed downward at a central portion of the support plate.

When the exhaust hole 144 is formed downward at the central portion of the support plate, the gas gathered at the central portion may be efficiently exhausted.

Meanwhile, when the mask M having at least one opening is closely attached to the substrate S, the substrate and the mask M need to be aligned with each other.

Accordingly, the substrate support unit 140 may further include at least one alignment unit (not shown) for aligning relative positions of the substrate S and the mask M.

The alignment unit for aligning the relative positions of the substrate S and the mask M may be installed above or below the substrate support unit 140 in a state in which the substrate S and the mask M are spaced from each other by using a lift pin and a clamp to align the relative positions of the substrate S and the mask M by the relative displacement between the substrate S and the mask M by using a camera.

Also, the number of the alignment unit may correspond to the number of substrates S supported by the substrate support unit 140 to further quickly align the substrate S with the mask M.

Meanwhile, although the substrate S and the mask M are closely attached to each other in the atomic layer deposition apparatus, the substrate S and the mask M may be coupled in advance at the outside and introduced into the atomic layer deposition apparatus.

In this case, the alignment between the substrate S and the mask M may not be necessary.

Meanwhile, a closely attaching unit for closely attaching the substrate to the mask such as a heater, a cooling plate, a clamp, and a magnet plate may be additionally installed on the substrate support unit 140 for the substrate processing process such as the thin film process.

When the plurality of rectangular substrates S are relatively rotated with respect to the gas injection unit 120 to perform the thin film deposition process at one time as described above, the speed of the thin film deposition process increases and also the installation space occupied by the system performing the process for the same number of the substrates may be minimized

Hereinafter, detailed constitution of the alignment unit will be described.

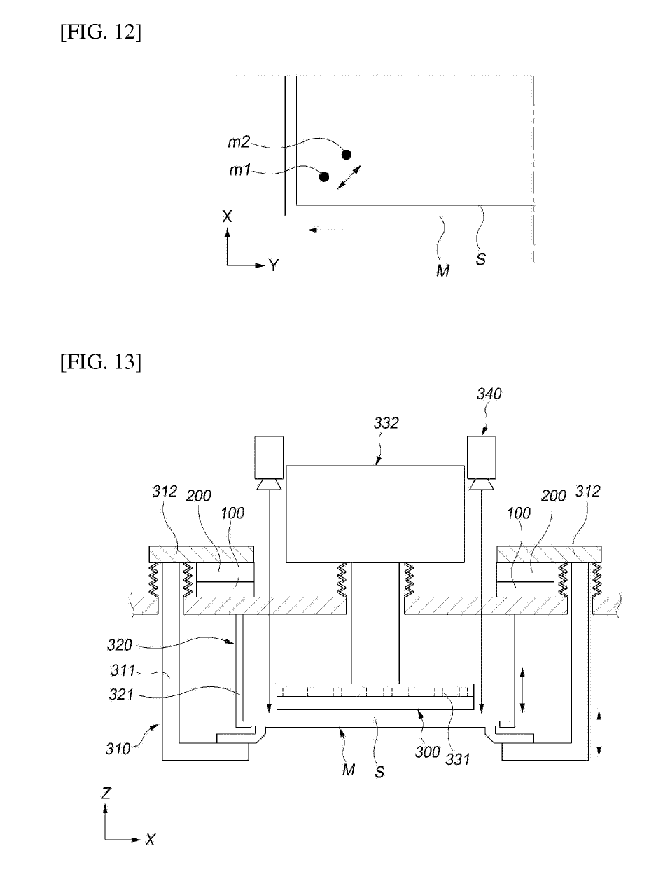

As shown in FIGS. 12 to 17, an alignment unit aligns the mask M with the substrate S before the thin film deposition process is performed on a surface of the substrate S and includes a first alignment unit 100 for sequentially and firstly aligning the substrate S with the mask M by performing first relative displacement between the substrate S and the mask M and a second alignment unit 200 for sequentially and secondarily aligning the substrate S with the mask M by performing second relative displacement between the substrate S and the mask M after the first alignment by the first alignment unit 100.

The alignment unit may be installed in a chamber having an inner space isolated from the outside, which is separated from the atomic layer deposition apparatus in FIG. 1 or mounted on a frame installed in a clean room having a cleaning environment.

Also, the alignment unit according to the present invention may be installed in the atomic layer deposition apparatus in FIG. 1 to align the mask M with the substrate S before performing a deposition process.

Meanwhile, the reason for performing the alignment between the substrate S and the mask M by using the first alignment unit 100 and the second alignment unit 200 is to quickly and precisely perform the alignment between the substrate S and the mask M through micro displacement by performing the second displacement M with a relatively small displacement scale after finishing the first displacement with a relatively large displacement scale when the substrate S and the mask M are relatively moved.

That is, a displacement scale of the second relative displacement is desirably less than that of the first relative displacement. For example, it is desirable that a displacement range of the first relative displacement is 5 μm to 10 μm, and a displacement range of the second relative displacement is desirably 10 nm to 5 μm.

Meanwhile, the substrate S and the mask M are supported by a substrate support unit 320 and a mask support unit 310, respectively.

The substrate support unit 320 supports an edge of the substrate S and desirably includes a plurality of support members 321 supporting the edge of the substrate S at a plurality of positions in consideration of size and center of gravity of the substrate S.

The plurality of support members 321 support the edge of the substrates S at the plurality of positions. The plurality of support members 321 may be up-down moved by an up-down movement unit (not shown) in consideration of attachment to the mask M.

The mask support unit 310 supports an edge of the mask M and desirably includes a plurality of support members 311 supporting the edge of the mask M at a plurality of positions in consideration of size and center of gravity of the mask M.

The plurality of support members 311 support the edge of the mask M at the plurality of positions. The plurality of support members 311 may be up-down moved by an up-down movement unit (not shown) in consideration of attachment to the substrate S.

The first alignment unit 100 sequentially and firstly aligns the substrate S with the mask M by the first relative displacement between the substrate S and the mask M.

The first alignment unit 100 may perform the relative displacement between the substrate S and the mask M in various methods. For example, while one of the substrate S and the mask M is fixed, the other is moved, or while both of the substrate S and the mask M are moved, the alignment between the substrate S and the mask M is performed.

Meanwhile, the first alignment unit 100 may be linearly driven by any one of a combination of ball screw, a combination of rack and pinion, and a combination of belt and pulley in consideration of the relatively large scale displacement in the displacement of the substrate S and the mask M.

As an embodiment in which the combination of the ball screw is applied, the first alignment unit 100, as shown in FIG. 13, may include a rotation motor 110, a screw member 130 rotated by the rotation motor 110, a linear movement member 120 coupled to the screw member 130 and linearly moved by the rotation of the screw member 130, and a movement member 140 coupled to the linear movement member 120 to move the substrate S or the mask M by the movement of the linear movement member 120.

Also, the first alignment unit 100 may include the appropriate number of the rotation motor 110, the screw member 130, the linear movement member 120, and the movement member 140 to correct X-axis deviation, Y-axis deviation, and θ-deviation (distortion between the mask and the substrate) with reference to the rectangular substrate S.

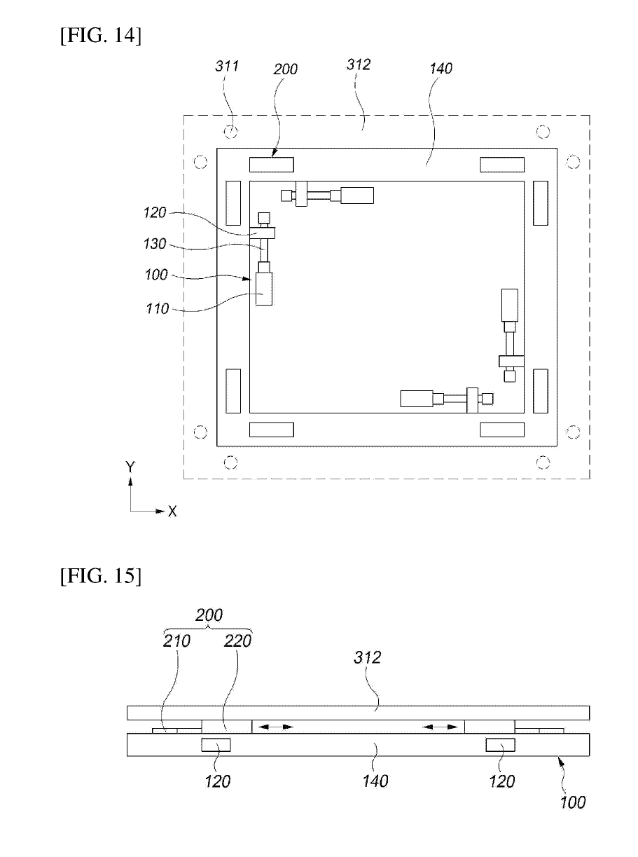

In case of an embodiment illustrated in FIGS. 13 and 14, the rotation motor 110, the screw member 130, the linear movement member 120, and the movement member 140 which constitute the first alignment unit 100, are provided in four to correspond to four sides of the mask M.

Also, the movement member 140 may support the second alignment unit 200 for supporting a movement block 312 of the mask support unit 310 and be indirectly coupled to the mask support unit 310.

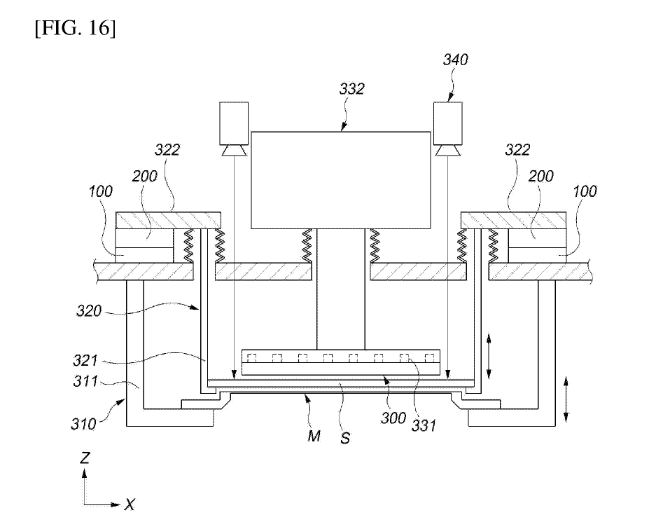

Here, the movement member 140 may have various embodiments depending on an object to be moved by the first alignment unit 100. For example, the movement member 140 may be directly or indirectly coupled to the mask support unit 310 or indirectly or directly coupled to the substrate support unit 320 as shown in FIGS. 16 and 17.

The second alignment unit 200 sequentially and secondarily aligns the substrate S with the mask M by the second relative displacement between the substrate S and the mask M after the first alignment by the first alignment unit 100.

The second alignment unit 200 may perform the relative displacement between the substrate S and the mask M in various methods. For example, while one of the substrate S and the mask M is fixed, the other is moved, or while both of the substrate S and the mask M are moved, the alignment between the substrate S and the mask M is performed.

Especially, the second alignment unit 200 is for displacement with a relatively small scale. The second alignment unit 200 may adapt any driving method as long as micro displacement in a range of 10 nm to 5 μm is possible and be desirably linearly-driven by, especially, piezoelectric element.

Since the piezoelectric element may precisely control the linear movement in the range of 10 nm to 5 μm, the piezoelectric element may be the best solution for correcting micro-deviation between the substrate S and the mask M.

As an embodiment in which the piezoelectric element is applied, as shown in FIG. 15, the second alignment unit 200 may include a linear driving unit 210 for generating a linear driving force by the piezoelectric element and a linear movement member 220 linearly moved by the linear driving force.

Also, the second alignment unit 200 may include the appropriate number of the linear driving unit 210 and the linear movement member 220 to correct X-axis deviation, Y-axis deviation, and θ-deviation (distortion between the mask and the substrate) with reference to the rectangular substrate S.

In case of the embodiment illustrated in FIGS. 13 and 14, the rotation motor 110, the screw member 130, the linear movement member 120, and the movement member 140 which constitute the first alignment unit 100, are installed to correspond to the four sides of the rectangular mask M.

Also, the linear movement member 220 may be directly coupled to the mask support unit 310 for supporting the movement block 312 of the mask support unit 310.

Here, the linear movement member 220 may have various embodiments depending on an object to be moved by the second alignment unit 200. For example, the linear movement member 220 may be directly or indirectly coupled to the mask support unit 310 as shown in FIGS. 16 and 17 or indirectly or directly coupled to the substrate support unit 320 although not shown.

As described above, the substrate and the mask may be quickly and precisely aligned with each other by performing the second relative displacement between the substrate S and the mask M with the relatively small displacement scale after finishing the first relative displacement between the substrate S and the mask M with a relatively large displacement scale by virtue of the constitution of the first alignment unit 100 and the second alignment unit 200.

Meanwhile, the above-described constitution of the first alignment unit 100 and the second alignment unit 200 may have various embodiments depending on the position and coupling structure thereof.

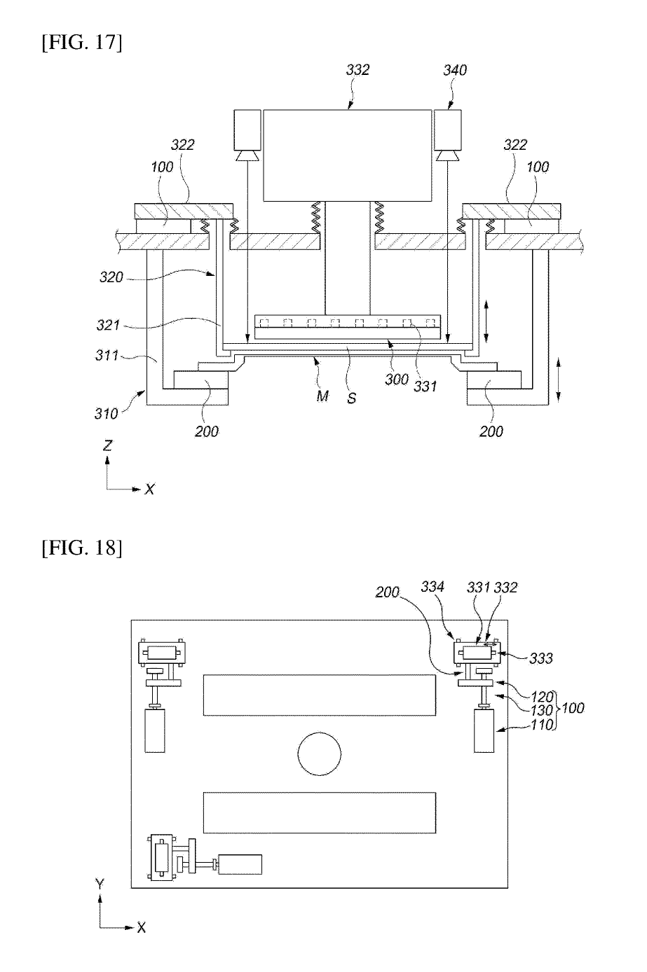

As shown in FIG. 18, in a modified example of the alignment unit, the alignment unit may include the first alignment unit 100 for driving the first relative displacement and the second alignment unit 200 for driving the second relative displacement after the first relative displacement by the first alignment unit 100.

Also, the first alignment unit 100 may include the rotation motor 110, the screw member 130 rotated by the rotation member 100, and the linear movement member 120 coupled to the screw member 130 and linearly moved by the rotation of the screw member 130.

Here, the screw member 130 may be rotatably supported by at least one bracket for being stably installed and rotated.

The second alignment unit 200 may include a linear micro-displacement member coupled to the linear movement member 120 so that the second alignment unit 200 is moved together with the first alignment unit 100 and linearly moving the movement block 312 connected to the support member for supporting the substrate S or the mask M.

Especially, the linear micro-displacement member of the second alignment unit 200 desirably includes piezo actuator, i.e., a linear driving module using the piezoelectric element.

The movement block 312 is coupled to the support member for supporting the substrate S or the mask M. The movement block 312 may include any component capable of transmitting the first relative displacement and the second relative displacement of the first alignment unit 100 and the second alignment unit 200 to the substrate S or the mask M.

Meanwhile, to stably perform the first relative displacement and the second relative displacement when the second alignment unit 200 is coupled to the movement block 312, the second alignment unit 200 may include a first support block 332 installed to be movable along at least one first guide rail 334 installed in a chamber or the like and linearly moved by the linear micro-displacement member and the second support block 331 installed to be movable along at least one second guide rail 333 supported by and installed on the first support block 332 to support the movement block 312.

The movement block 312 may be stably supported and the first relative displacement and the second relative displacement may be smoothly performed by the constitution of the first support block 332 and the second support block 331.

The appropriate number, such as three, of the first alignment unit 100 and the second alignment unit 200, which have the above-described constitution, may be installed to correct the X-axis deviation, the Y-axis deviation, and the θ-deviation (distortion between the mask and the substrate) with reference to the rectangular substrate S.

Meanwhile, the first alignment unit 100 and the second alignment unit 200 may have various embodiments depending on the coupling structure and the installation position in the relative displacement between the substrate S and the mask M.

As shown in FIG. 13, in the alignment unit according to the first embodiment, the first alignment unit 100 and the second alignment unit 200 may be are coupled to the mask support unit 310 for supporting the mask M and move the mask support unit 310, thereby performing the first relative displacement and the second relative displacement of the mask M supported by the mask support unit 310 with respect to the substrate S.

On the contrary to the first embodiment, as shown in FIG. 16, in the alignment unit according to a second embodiment, the first alignment unit 100 and the second alignment unit 200 may be coupled to the substrate support unit 320 for supporting the substrate S and move the substrate support unit 320, thereby performing the first relative displacement and the second relative displacement of the substrate S supported by the substrate support unit 320 with respect to the mask M.

As shown in FIG. 17, in an alignment unit according to a third embodiment, the second alignment unit 200 may be coupled to the mask support unit 310 for supporting the mask M and move the mask support unit 310, thereby performing the second relative displacement of the mask M supported by the mask support unit 310 with respect to the substrate S, and the first alignment unit 100 may be coupled to the substrate support unit 320 for supporting the substrate S and move the substrate support unit 320, thereby performing the first relative displacement of the substrate S supported by the substrate support unit 320 with respect to the mask M.

On the contrary to the third embodiment, in an aligner structure according to a fourth embodiment, the first alignment unit 100 may be coupled to the mask support unit 310 for supporting the mask M and move the mask support unit 310, thereby performing the first relative displacement of the mask M supported by the mask support unit 310 with respect to the substrate S, and the second alignment unit 200 may be coupled to the substrate support unit 320 for supporting the substrate S and move the substrate support unit 320, thereby performing the second relative displacement of the substrate S supported by the substrate support unit 320 with respect to the mask M.

Meanwhile, although embodiments of the present invention are described when a direction in which the mask M is closely attached to the substrate S is from a lower side to an upper side, the alignment unit may be applied when the direction in which the mask M is closely attached to the substrate S is from the upper side to the lower side and when the mask M is horizontally attached to the substrate S while the substrate S is vertically disposed.

In other words, the alignment unit may be applied when the process is performed in a state in which a surface to be processed of the substrate faces downward, when the process is performed in a state in which the surface to be processed of the substrate faces upward, and when the process is performed in a state in which the surface to be processed of the substrate is perpendicular to the horizontal line.

Reference number 340 indicates a camera for recognizing marks m1 and m2 respectively formed in the substrate S and the mask M. Reference number 300 indicates a support means closely attaching the mask M to support the substrate S by using a plurality of magnets 331 installed therein after the alignment between the substrate S and the mask M, and Reference number 332 indicates a rotation motor rotating the support unit 300 for a thin film deposition or the like after the mask M is closely attached to the substrate S. The above-described numerical numbers are not described in FIGS. 13, 16, and 17.

The support means 300 supports the other side of the substrate S to which the mask M is closely attached. The support unit 300 may include a carrier moved while supporting the substrate S or a susceptor installed in a vacuum chamber.

As shown in FIG. 21, at least one damping member 120 may be installed on the support means 300 to prevent excessive shock to the substrate S when the mask M is closely attached to the substrate S.

The damping member 120 may be made of flexible material such as rubber.

Also, a plurality of detection sensors 150 may be additionally installed on the support means 300 to detect a distance between the substrate S and the mask M when the substrate S and the mask M are aligned, i.e., arranged.

The detection sensor 150 such as an ultrasonic sensor for detecting a distance may detect the distance between the substrate S and the mask M so that a controller (not shown) of the apparatus determines whether the substrate S and the mask M contact to each other or have an alignable distance.

The above-described detection sensor 150 may transmit a signal to the controller of the apparatus through wireless communications or through wire by a signal transmit member 130 that is separately installed.

Also, the detection sensor 150 may be installed at a plurality of positions to calculate a degree of parallelization between the substrate S and the mask M and control the degree of parallelization between the substrate S and the mask M by a parallelization degree adjustment device (not shown) that will be described later.

As described above, the combination of the first alignment unit 100 and the second alignment unit 200 may have various embodiments depending on the installation position and coupling structure thereof.

Meanwhile, according to an aspect of the present invention, the present invention provides a quick alignment method between the substrate S and the mask M.

In detail, the alignment method includes a closely attaching process of closely attaching the substrate S to the mask M and an alignment process of aligning the substrate S with the mask M. Here, the closely attaching process and the alignment process are performed at the same time.

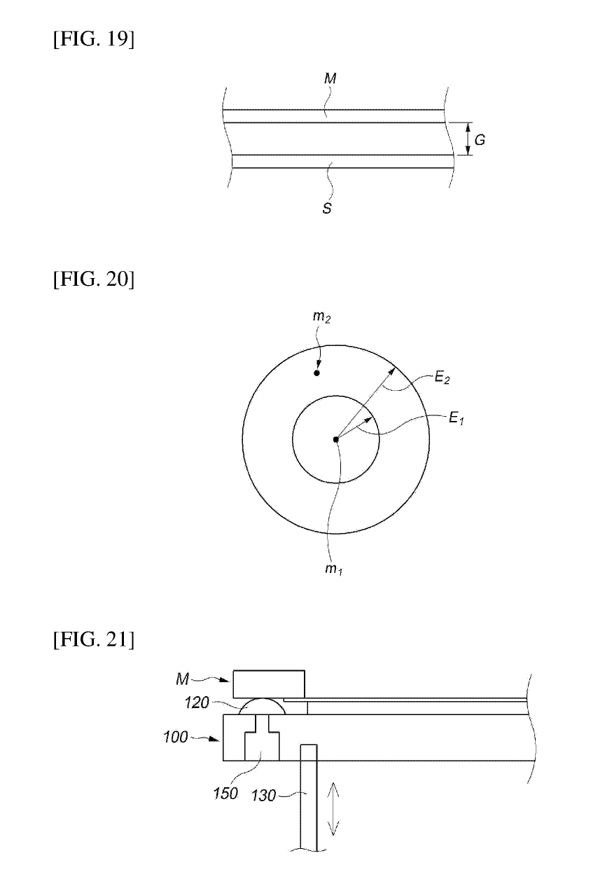

Especially, the alignment method performs the closely attaching process of closely attaching the substrate S to the mask M first, and, when the relative distance between the substrate S and the mask M has a predetermined value G as shown in FIG. 19, the closely attaching process and the alignment process are desirably performed at the same time.

Here, a distance sensor 150 for detecting a distance between the substrate S and the mask M may be installed in the chamber or the like.

The distance sensor for detecting the distance between the substrate S to the mask M may include any sensor capable of detecting a distance, e.g., an ultrasonic sensor 150.

As described above, when the closely attaching process and the alignment process are simultaneously performed, a time for performing a process may be minimized in comparison with that of a related art which performs the alignment process in a state in which the distance between the substrate S and the mask M is fixed.

Also, in comparison with the related art that performs the alignment process in a state in which the distance between the substrate S and the mask M is fixed, the alignment process may be further exactly performed because the alignment process is performed in a state in which the distance between the substrate S and the mask M is small.

Also, as the alignment process is quickly and exactly performed, failure of substrate processing may be minimized.

The above-described alignment method may be certainly applied regardless of the alignment structure for alignment between the substrate S and the mask M.

In general, in performing the alignment process for the substrate S and the mask M, the alignment process for the substrate S and the mask M is performed, the closely attaching the substrate S to the mask M and an alignment determination measurement within a predetermined allowable error range E₁ are performed (refer to FIG. 20), and, when an error of the result measured from the alignment determination measurement is greater than the allowable error range E₁, the substrate S and the mask M are separated again and then the alignment process and the alignment determination measurement are performed again.

However, when the alignment process for the substrate S and the mask M is not smoothly performed, the alignment process and the alignment determination measurement are performed by several times to thereby increase the total time for performing the process.

To solve the above-described problems, the present invention may perform an assistant alignment process for performing the alignment between the substrate S and the mask M in the state in which the substrate S and the mask M are closely attached to each other without separating the substrate S from the mask M when the error measured from the alignment determination measurement is greater than the allowable error range E₁ and less than a predetermined assistant allowable error range E₂.

Here, when the error measured from the alignment determination measurement is greater than the assistant allowable error range E₂, certainly, the substrate S and the mask M are separated from each other again, and then the alignment process and the alignment determination measurement are performed again.

Also, the assistant alignment process is desirably performed by a linear driving device capable of driving linear micro-displacement in consideration of relative linear micro-displacement between the substrate S and the mask M.

Especially, the linear driving device capable of driving the linear micro-displacement may include the above-described piezoactuator.

When the alignment process for the substrate S and the mask M is completed, the substrate S and the mask M, which are closely attached to each other, are chucked by a permanent magnet or the like.

When the alignment process for the substrate S and the mask M is performed as described above, as the alignment between the substrate S and the mask M is performed in the state in which the substrate S and the mask M are closely attached to each other according to the measurement result, the alignment process may be more quickly and exactly performed.

Also, as the alignment process is quickly and exactly performed, the failure of substrate processing may be minimized

The above-described alignment method may be certainly applied regardless of the alignment structure for alignment between the substrate S to the mask M.

Meanwhile, in the above-described alignment and attachment between the substrate S and the mask M, the substrate S and the mask M are necessary to be parallel to each other.

As the degree of parallelization between the substrate S and the mask M is measured by using the above-described plurality of distance sensors 150 and at least one of the substrate support unit 320 and the mask support unit 310, which respectively support the substrate S and the mask M, is up-down moved by the parallelization degree adjustment device, the substrate S and the mask M may maintain the state parallel to each other.

As the parallelization degree adjustment device up-down moves at least one of the substrate support unit 320 and the mask support unit 310, which respectively support the substrate S and the mask M, the parallelization degree adjustment device controls the state in which the substrate S and the mask M are parallel to each other.

In detail, each of the substrate support unit 320 and the mask support unit 310 includes the plurality of support members 321 and 311 supporting the edge of the substrate S and the mask M in a horizontal state and in a plurality of positions of the edge of the substrate S and the mask M. Here, up-down displacement deviation is applied to a portion of the support members 321 and 311 disposed on the plurality of positions, so that the state in which the substrate S and the mask M are parallel to each other is controlled.

When the state in which the substrate S and the mask M are parallel to each other is maintained by the above-described parallelization degree adjustment device, the substrate S and the mask M may be precisely aligned with and stably attached to each other.

Especially, the parallelization degree adjustment device may be combined with the first alignment unit 100 and the second alignment unit 200 or installed on the substrate support unit 320 to prevent interference when the first alignment unit 100 and the second alignment unit 200 are installed on the mask support unit 310.

Also, the parallelization degree adjustment device may include all components for up-down linear movement, e.g., a screw jack installed in the vacuum chamber in consideration of an up-down ascending/descending operation.

1. An atomic layer deposition apparatus comprising:
a vacuum chamber;
a gas injection unit installed above or below the vacuum chamber to supply a gas so that a thin film is deposited on a surface of a substrate; and
a substrate support unit installed in the vacuum chamber to relatively and horizontally rotate with respect to the gas injection unit and supporting two or more rectangular substrates arranged in a circumferential direction with respect to a center of rotation thereof,
wherein the gas injection unit comprises at least one source gas injection unit arranged in a rotational direction of the substrate to spray source gas and at least one reaction gas injection unit for spraying reaction gas that is in a plasma state,
an exhaust unit for absorbing and exhausting the gas is installed on at least one area between the injection units,
a mask having at least one opening defined in a surface, which faces the gas injection unit, is closely attached to the substrate supported by the substrate support unit, and
the atomic layer deposition apparatus further comprises at least one alignment unit for aligning relative positions of the substrate and the mask.

2. The atomic layer deposition apparatus of claim 1, wherein the alignment unit is installed corresponding to the number of the substrates supported by the substrate support unit.

3. The atomic layer deposition apparatus of claim 1, wherein the alignment unit for aligning the mask (M) with the substrate (S) before performing the thin film deposition process on the surface of the substrate (S) includes:
a first alignment unit (100) for sequentially and firstly aligning the substrate (S) with the mask (M) by first relative displacement between the substrate (S) and the mask (M); and
a second alignment unit (200) for sequentially and secondarily aligning the substrate (S) with the mask (M) by second relative displacement between the substrate (S) and the mask (M) after the first alignment by the first alignment unit (100),
wherein a displacement scale of the second relative displacement is less than that of the first relative displacement.

4. The atomic layer deposition apparatus of claim 3, wherein the first alignment unit (100) and the second alignment unit (200) are coupled to a mask support unit (310) for supporting the mask (M) to move the mask support unit (310), thereby performing the first relative displacement and the second relative displacement of the mask (M) supported by the mask support unit (310) with respect to the substrate (S).

5. The atomic layer deposition apparatus of claim 3, wherein the first alignment unit (100) and the second alignment unit (200) are coupled to a substrate support unit (320) for supporting the substrate (S) to move the substrate support unit (320), thereby performing the first relative displacement and the second relative displacement of the substrate (S) supported by the substrate support unit (320) with respect to the mask (M).

6. The atomic layer deposition apparatus of claim 3, wherein the second alignment unit (200) is coupled to a mask support unit (310) for supporting the mask (M) to move the mask support unit (310), thereby performing the second relative displacement of the mask (M) supported by the mask support unit (310) with respect to the substrate (S), and
the first alignment unit (100) is coupled to a substrate support unit (320) for supporting the substrate (S) to move the substrate support unit (320), thereby performing the first relative displacement of the substrate (S) supported by the substrate support unit (320) with respect to the mask (M).

7. The atomic layer deposition apparatus of claim 3, wherein the first alignment unit (100) is coupled to a mask support unit (310) for supporting the mask (M) to move the mask support unit (310), thereby performing the first relative displacement of the mask (M) supported by the mask support unit (310) with respect to the substrate (S), and
the second alignment unit (200) is coupled to a substrate support unit (320) for supporting the substrate (S) to move the substrate support unit (320), thereby performing the second relative displacement of the substrate (S) supported by the substrate support unit (320) with respect to the mask (M).

8. An atomic layer deposition system comprising:
at least one transfer apparatus in which a transfer robot is installed; and
a plurality of atomic layer deposition apparatuses of claim 1, the plurality of atomic layer deposition apparatuses being coupled to the transfer apparatus to receive a substrate by the transfer robot.

9. An atomic layer deposition system comprising:
at least one transfer apparatus in which a transfer robot is installed; and
a plurality of atomic layer deposition apparatuses of claim 2, the plurality of atomic layer deposition apparatuses being coupled to the transfer apparatus to receive a substrate by the transfer robot.

10. An atomic layer deposition system comprising:
at least one transfer apparatus in which a transfer robot is installed; and
a plurality of atomic layer deposition apparatuses of claim 3, the plurality of atomic layer deposition apparatuses being coupled to the transfer apparatus to receive a substrate by the transfer robot.

11. An atomic layer deposition system comprising:
at least one transfer apparatus in which a transfer robot is installed; and
a plurality of atomic layer deposition apparatuses of claim 4, the plurality of atomic layer deposition apparatuses being coupled to the transfer apparatus to receive a substrate by the transfer robot.

12. An atomic layer deposition system comprising:
at least one transfer apparatus in which a transfer robot is installed; and
a plurality of atomic layer deposition apparatuses of claim 5, the plurality of atomic layer deposition apparatuses being coupled to the transfer apparatus to receive a substrate by the transfer robot.

13. An atomic layer deposition system comprising:
at least one transfer apparatus in which a transfer robot is installed; and
a plurality of atomic layer deposition apparatuses of claim 6, the plurality of atomic layer deposition apparatuses being coupled to the transfer apparatus to receive a substrate by the transfer robot.

14. An atomic layer deposition system comprising:
at least one transfer apparatus in which a transfer robot is installed; and
a plurality of atomic layer deposition apparatuses of claim 7, the plurality of atomic layer deposition apparatuses being coupled to the transfer apparatus to receive a substrate by the transfer robot.
